(19) United States
(12) Patent Application Publication
(10) Pub. No.: US 2015/0108450 A1
(43) Pub. Date: Apr. 23, 2015

(54) THIN-FILM TRANSISTOR ARRAY SUBSTRATE, ORGANIC LIGHT-EMITTING DISPLAY APPARATUS, AND MANUFACTURING METHOD THEREOF

(71) Applicant: Samsung Display Co., Ltd., Yongin-City (KR)

(72) Inventors: Yong-Duck Son, Yongin-City (KR); Shin-Moon Kang, Yongin-City (KR); Il-Hun Seo, Yongin-City (KR); Jong-Hyun Choi, Yongin-City (KR)

(21) Appl. No.: 14/469,355

(22) Filed: Aug. 26, 2014

(30) Foreign Application Priority Data
Oct. 17, 2013 (KR) 10-2013-0124162

(51) Int. Cl. H01L 27/32; H01L 21/3213; H01L 27/12

(52) U.S. Cl. CPC H01L 27/3262; H01L 27/124; H01L 27/1255; H01L 27/1259; H01L 21/32139
USPC 257/40; 257/72; 438/158

(57) ABSTRACT

A thin film transistor (TFT) array substrate, an organic light-emitting display apparatus, and a manufacturing method thereof are disclosed. One inventive aspect includes a first gate line formed on a substrate and a second gate line formed on the first gate line. A third gate line is formed on the second gate line and covers a top surface of the second gate line and the side portions of the first and second gate lines.

### CROSS-REFERENCE TO RELATED APPLICATIONS

This application claims the benefit of Korean Patent Application No. 10-2013-0124162, filed on Oct. 17, 2013, in the Korean Intellectual Property Office, the disclosures of which are incorporated herein in their entirety by reference.

### BACKGROUND

1. Field

The disclosed technology relate to a thin film transistor (TFT) array substrate, an organic light-emitting display apparatus, and a manufacturing method thereof with reduced gate line and data line short circuits, reduced data line disconnections and therefore, improved TFT characteristics.

2. Description of the Related Technology

A display apparatus, such as an organic light-emitting display device, a liquid crystal display device, or the like, includes a thin film transistor (TFT), a capacitor, and a plurality of wirings. Further, the substrate used to manufacture the display apparatus includes micro-patterns for TFTs, capacitors, and wirings, and the like, and the display apparatus operates by complicated connections between the TFTs, capacitors, and wirings, and the like.

As a self-luminance display, an organic light-emitting display apparatus requires no separate light source. It includes an organic light-emitting device which emits light as excitons. The excitons are generated as holes, which are injected by a hole injection electrode, and electrons, which are injected by an electron injection electrode. The organic light-emitting device further includes an organic emission layer formed therebetween and emits light when excitons formed by combining holes of the hole injection electrode and electrons of the electron injection electrode drop from an excited state to a ground state.

Therefore, organic light-emitting display apparatuses that are self-emitting display devices has a range of applications extending from personal mobile devices, such as MP3 players or cell phones to televisions. They are also driven at a low voltage, lightweight and thin, and have wide viewing angles in addition to high contrast and a quick response speed.

### SUMMARY OF CERTAIN INVENTIVE ASPECTS

Various exemplary embodiments of the present invention include a thin film transistor (TFT) array substrate, an organic light-emitting display apparatus, and a manufacturing method thereof.

Additional aspects will be set forth in part in the description which follows and, in part, will be apparent from the description, or may be learned by practice of the presented embodiments.

According to one aspect of the disclosed technology, a thin film transistor (TFT) array substrate includes a first gate line formed on a substrate, a second gate line formed on the first gate line, and a third gate line that is formed on the second gate line and covers a top surface of the second gate line and side portions of the first gate line and the second gate line.

The third gate line can include a first area that covers the first gate line and the second gate line, and second areas extended from the first area in a direction that is changed to be parallel to the substrate.

The second gate line can include aluminum (Al).

The first gate line and the second gate line can have the same etching surfaces.

An angle between the substrate and the etching surface of the second gate line can be 50 degrees or less.

The TFT array substrate can further include an interlayer insulating layer formed on the third gate line and a data line formed on the interlayer insulating layer.

The TFT array substrate can further include a TFT formed on the substrate, wherein the TFT includes an active layer comprising a channel area, a source area, and a drain area, a gate electrode that is insulated from the active layer and formed on an area corresponding to the channel area, and a source electrode and a drain electrode that are each respectively electrically connected with the source area and the drain area of the active layer and formed on the same layer with the data line.

The gate electrode can include a first gate electrode, a second gate electrode, and a third gate electrode that are each respectively formed on the same layer with the first gate line, the second gate line, and the third gate line, wherein the third gate electrode comprises a first area that covers the first gate electrode and the second gate electrode and second areas extended from the first area in a direction that is changed to be parallel to the substrate.

The active layer can include a channel area that is formed in an area corresponding to the first area of the third gate electrode and a source area and a drain area that are corresponded to both edges of the channel area and doped with impurities, wherein areas of the source area and the drain area that are corresponded to the second areas of the third gate electrode are doped with a less amount of impurities compared to other areas of the source area and the drain area.

According to another aspect of the disclosed technology, a manufacturing method includes forming a first gate line material and a second gate line material on a substrate, forming a first gate line and a second gate line by patterning the first gate line material and the second gate line material, forming a third gate line material on the second gate line, and forming a third gate line that covers a top surface of the second gate line and side portions of the first gate line by patterning the third gate line material.

The forming of the first gate line and the second gate line can include forming the first gate line and the second gate line by patterning the first gate line material and the second gate line material by using a first mask, and the forming of the third gate line comprises forming of the third gate line by patterning the third gate line material by using a second mask.

A width of an opening of the first mask corresponding to the first gate line and the second gate line can be the same with a width of an opening of the second mask corresponding to the third gate line.

A width of an opening of the first mask corresponding to the first gate line and the second gate line can be smaller than a width of an opening of the second mask corresponding to the third gate line.

The method can further include forming an interlayer insulating layer on the third gate line and forming a data line on the interlayer insulating layer.

The method can further include forming a TFT on the substrate, wherein the forming of the TFT includes forming an active layer on the substrate, forming a gate insulating layer and a gate electrode on the active layer, and forming a source electrode and a drain electrode on the gate electrode.

The forming of the third gate electrode can include forming the third gate electrode that comprises a first area that covers the first gate electrode and the second gate electrode and second areas extended from the first area in a direction that is changed to be parallel to the substrate.

The method can further include doping impurities in the active layer by using the first gate electrode, the second gate electrode, and the third gate electrode as a mask.

According to another aspect of the disclosed technology, an organic light-emitting display apparatus includes a plurality of gate lines that are extended in a first direction, a plurality of data lines that are insulated from the gate lines by an interlayer insulating layer and extended in a second direction intersecting the first direction, a pixel that is electrically connected to the gate lines and the data lines and comprises a TFT, and an organic light-emitting device that is included in the pixel, electrically connected with the TFT, and comprises a pixel electrode, a counter electrode, and an intermediate layer, which is formed between the pixel electrode and the counter electrode and emits light, wherein one of the gate lines comprises: a first gate line formed on a substrate, a second gate line formed on the first gate line, and a third gate line that is formed on the second gate line and covers a top surface of the second gate line and side portions of the first gate line and the second gate line.

The TFT can include an active layer comprising a channel area, a source area, and a drain area, a gate electrode that is insulated from the active layer and formed on an area corresponding to the channel area, and a source electrode and a drain electrode that are each respectively electrically connected with the source area and the drain area of the active layer and formed on the same layer with the data line, wherein the organic light-emitting apparatus further comprises a pad electrode comprising a first pad layer that is formed on the same layer with the source electrode and the drain electrode and a second pad layer formed on the first pad layer, a capacitor comprising a first electrode formed on the same layer with the active layer, a second electrode formed on the same layer with the gate electrode, and a third electrode formed on the same layer with the source and drain electrodes, a planarization layer that covers the source and drain electrode and comprises an opening in which the pixel electrode is formed, and a pixel defining layer comprising an opening formed in an area corresponding to the opening comprised in the planarization layer and covers side portions of the pixel electrode.

Aspects, features, and advantages other than those described above will be clearly understood by drawings, claims, and the detailed description of the disclosed technology.

### BRIEF DESCRIPTION OF THE DRAWINGS

These and/or other aspects will become apparent and more readily appreciated from the following description of the embodiments, taken in conjunction with the accompanying drawings in which:

FIG. 1 is a cross-sectional view schematically illustrating a thin film transistor (TFT) array substrate according to an embodiment of the disclosed technology;

FIG. 2 is a cross-sectional view schematically illustrating a TFT array substrate according to another embodiment of the disclosed technology;

FIGS. 3 to 12 are cross-sectional views sequentially illustrating a process of manufacturing the TFT array substrate in FIG. 1;

FIGS. 13 to 15 are cross-sectional views sequentially illustrating a part of a process of manufacturing the TFT array substrate in FIG. 2; and

FIG. 16 is a cross-sectional view schematically illustrating an organic light-emitting display apparatus according to an embodiment of the disclosed technology.

### DETAILED DESCRIPTION OF CERTAIN INVENTIVE EMBODIMENTS

Reference will now be made in detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

In the following description, technical terms are used only to explain a specific exemplary embodiment while not limiting the disclosed technology. The terms of a singular form may include plural forms unless referred to the contrary. The terms “include,” “comprise,” “including,” and “comprising,” as used herein, specify a component, a process, an operation, and/or an element but do not exclude other components, processes, operations, and/or elements. It will be understood that although the terms “first” and “second” are used herein to describe various elements, these elements should not be limited by these terms. These terms are only used to distinguish one component from other components.

It will be understood that when a layer, region, or component is referred to as being “formed on,” another layer, region, or component, it can be directly or indirectly formed on the other layer, region, or component. That is, for example, intervening layers, regions, or components may be present.

The drawings and description are to be regarded as illustrative in nature and not restrictive. Like reference numerals designate like elements throughout the specification.

Further, since sizes and thicknesses of constituent members shown in the accompanying drawings are arbitrarily given for better understanding and ease of description, the disclosed technology is not limited to the illustrated sizes and thicknesses.

In the drawings, the thickness of layers, films, panels, regions, etc., are exaggerated for clarity. In the drawings, for better understanding and ease of description, the thicknesses of some layers and areas are exaggerated. It will be understood that when an element such as a layer, film, region, or substrate is referred to as being “on” another element, it is directly on the other element or intervening elements may also be present.

Throughout this specification and the claims that follow, when it is described that an element is “connected” to another element, the element is “directly connected” to the other element or “electrically connected” to the other element through a third element. In addition, unless explicitly described to the contrary, the word “comprise” and variations such as “comprises” or “comprising” will be understood to imply the inclusion of stated elements but not the exclusion of any other elements. Throughout this specification, it is understood that the term “on” and similar terms are used generally and are not necessarily related to a gravitational reference.

Here, when a first element is described as being connected to a second element, the first element is not only directly connected to the second element but may also be indirectly connected to the second element via a third element. Further, some of the elements that are not essential to the complete understanding of the disclosed technology are omitted for clarity. Also, like reference numerals refer to like elements throughout.

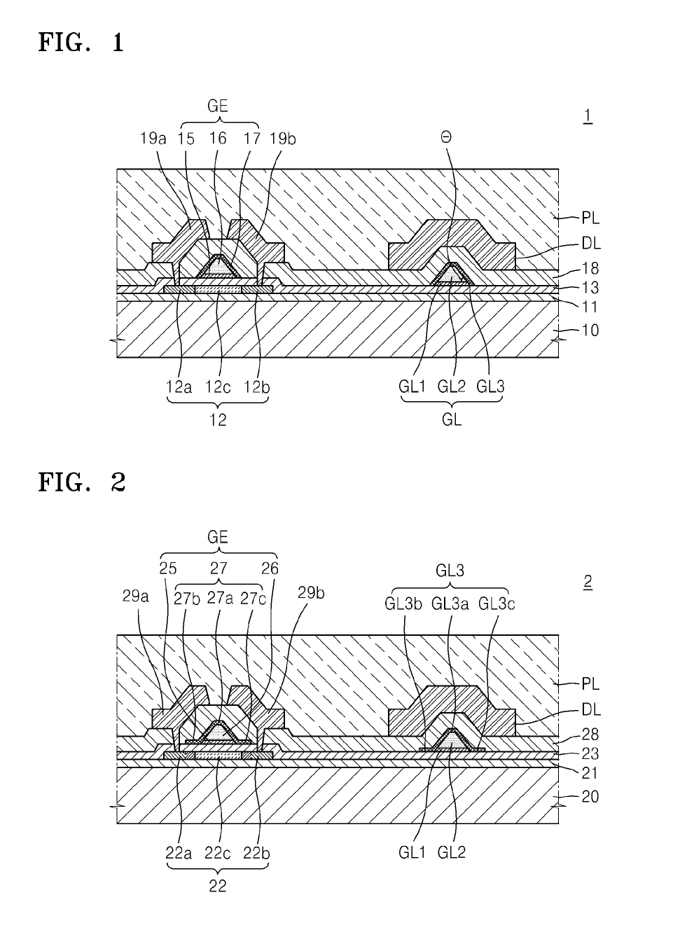

FIG. 1 is a cross-sectional view schematically illustrating a thin film transistor (TFT) array substrate 1 according to an embodiment of the disclosed technology.

Referring to FIG. 1, the TFT array substrate 1 includes a first gate line GL1 formed on a substrate 10, a second gate line GL2 formed on the first gate line GL1, and a third gate line GL3. The third gate line GL3 covers a top surface of the second gate line GL2 and the side portions of the first gate line GL1 and second gate line GL2.

Moreover, an interlayer insulating layer 18 may be formed on the third gate line GL3. A data line DL may be formed on the interlayer insulating layer 18. The array substrate 10 according to the current embodiment may include a plurality of gate lines GL and a plurality of data lines DL. The gate lines GL and the data lines DL may be extended in different directions from each other.

FIG. 1 illustrates a cross-sectional view of an area where one of the gate lines GL and one of the data lines DL are overlapped for descriptive convenience.

The TFT array substrate 1 according to the current embodiment may further include a TFT. A TFT shown in FIG. 1 may be one of a driving TFT, a switching TFT, or a TFT having another function.

The TFT includes an active layer 12, a gate electrode GE, a source electrode 19a, and a drain electrode 19b. The gate electrode GE may be formed on the same layer and formed with the same material of the gate line GL. That is, the gate electrode GE may include a first gate electrode 15 formed on the same layer with the first gate line GL1, a second gate electrode 16 formed on the same layer with the second gate line GL2, and a third gate electrode 17. The third gate electrode 17 is formed on the same layer with the third gate line GL3 and covers a top surface of the second gate electrode 16 and the side portions of the first gate electrode 15 and the second gate electrode 16.

The active layer 12 may be formed to contain various materials. In one exemplary implementation, the active layer 12 may be formed of an inorganic semiconductor material, such as amorphous silicon or crystalline silicon. In this regard, the active layer 12 includes a channel area 12c, a source area 12a and a drain area 12b. The source area 12a and the drain area 12b are doped with ion impurities and formed at both edges of the channel area 12c, one at each of the edges. Alternatively, the active layer 12 may include an oxide conductor. The active layer 12 may include an organic semiconductor material.

A buffer layer 11 may be formed between the active layer 12 and the substrate 10. A gate insulating layer 13 may be formed between the active layer 12 and the gate electrode GE.

The source electrode 19a and the drain electrode 19b may be formed on the same layer and formed with the same material of the data line DL. A planarization layer PL may be formed on the data line DL so as to cover the data line DL, the source electrode 19a and the drain electrode 19b.

The source electrode 19a and the drain electrode 19b may include at least 2 metal layers each metal selected from aluminum (Al), platinum (Pt), palladium (Pd), silver (Ag), magnesium (Mg), gold (Au), nickel (Ni), neodymium (Nd), iridium (Ir), chrom (Cr), lithium (Li), calcium (Ca), molybdenum (Mo), titanium (Ti), tungsten (W), copper (Cu), and an alloy thereof.

The first gate line GL1 and the third gate line GL3 may be formed of the same materials, such as, Mo or Ti. The second gate line GL2 may be formed of a metal with high electric conductivity, such as Al or Cu.

The first gate line GL1 and the second gate line GL2 may have the same etching surfaces, and an angle (θ) formed by etching surfaces of the substrate 10 and the second gate line GL2 may be 50 degrees or less. The angle will be described later in detail.

The third gate line GL3 is formed to cover a top surface of the second gate line GL2 and the side portions of the first gate line GL1 and the second gate line GL2. Thus, the third gate line GL3 serves as a protection layer at a high temperature when or after forming the gate lines GL and when Al included in the second gate line GL2 penetrates into the interlayer insulating layer 18. Thus, short circuits occurring in the gate line GL and a data line DL may be prevented.

The active layer 12 included in the TFT may be activated by a high-temperature process. However, the second gate line GL2 included in the gate line GL may penetrate into the interlayer insulating layer 18 at the high temperature. Therefore, the increased temperature is limited.

However, in one exemplary embodiment, the high-temperature process at a temperature of 600° C. or higher is possible. A charge carrier mobility of the active layer 12 may increase compared to a case when the active layer 12 is activated at a temperature lower than this.

FIG. 2 is a schematic cross-sectional view of a TFT array substrate 2 according to another embodiment of the disclosed technology.

Referring to FIG. 2, the TFT array substrate 2 includes a first gate line GL1 formed on a substrate 20, a second gate line GL2 formed on the first gate line GL1, and a third gate line GL3. The third gate line GL3 is formed on the second gate line GL2 and covers a top surface of the second gate line GL2 and the side portions of the first gate line GL1 and the second gate line GL2.

An interlayer insulating layer 28 may be formed on the third gate line GL3, and a data line DL. A planarization layer PL covering the data line DL may be formed on the interlayer insulating layer 28.

The TFT array substrate 2 may further include a TFT. The TFT may include an active layer 22, a gate electrode GE, a source electrode 29a, and a drain electrode 29b. The active layer 22 includes a source area 22a, a drain area 22b, and a channel area 22c. The gate electrode GE may be formed on the same layer with the gate line GL. That is, the gate electrode GE may include a first gate electrode 25 formed on the same layer with the first gate line GL1, a second gate electrode 26 formed on the same layer with the second gate line GL2, and a third gate electrode 27. The third gate electrode 27 is formed on the same layer with the third gate line GL3 and covers the first gate electrode 25 and the second gate electrode 26.

Other elements of the TFT array substrate 2 are the same with those of the TFT array substrate 1 shown in FIG. 1, but only the third gate line GL3 and the third gate electrode 27 are different from those of the TFT array substrate 1 shown in FIG. 1.

The third gate line GL3 may include a first area GL3a covering the first gate line GL1 and the second gate line GL2; and second areas GL3b and GL3c, which are extended from the first area GL3a in a direction that is changed to be parallel to the substrate 20.

The third gate electrode 27, as well as the third gate line GL3, may include a first area 27a covering the first gate electrode 25 and the second gate electrode 26; and second areas 27b and 27c, which are extended from the first area 27a in a direction that is changed to be parallel to the substrate 20.

The gate electrode GE serves as a mask when doping impurities of the active layer 22 in a manufacturing process of the TFT array substrate 2.

Thus, an amount of the impurities doped in the active layer 22 may vary depending on a shape and a thickness of the gate electrode GE. The active layer 22 of the present embodiment includes a channel area 22c formed on an area corresponding to the first area 27a of the third gate electrode 27, a source area 22a and a drain area 22b. The source area 22a and the drain area 22b are formed on each of both edges of the channel area 22c. Impurities may be less doped in areas of the a source area 22a and the drain area 22b corresponding to the second areas 27b and 27c of the third gate electrode compared to the area other than the source area 22a and the drain area 22b.

A thickness of the second areas 27b and 27c of the third gate electrode 27 is thin enough to dope impurities in the active layer 22, but an amount of the doped impurities may be less than an amount of the impurities doped in an area of the active layer 22 corresponding to an area, on which the third gate electrode 27 is not formed. That is, the second areas 27b and 27c of the third gate electrode 27 may serve as a halftone mask.

A length of the second areas 27b and 27c of the third gate electrode 27 may be controlled by controlling a width of a mask that is used in patterning the third gate electrode 27.

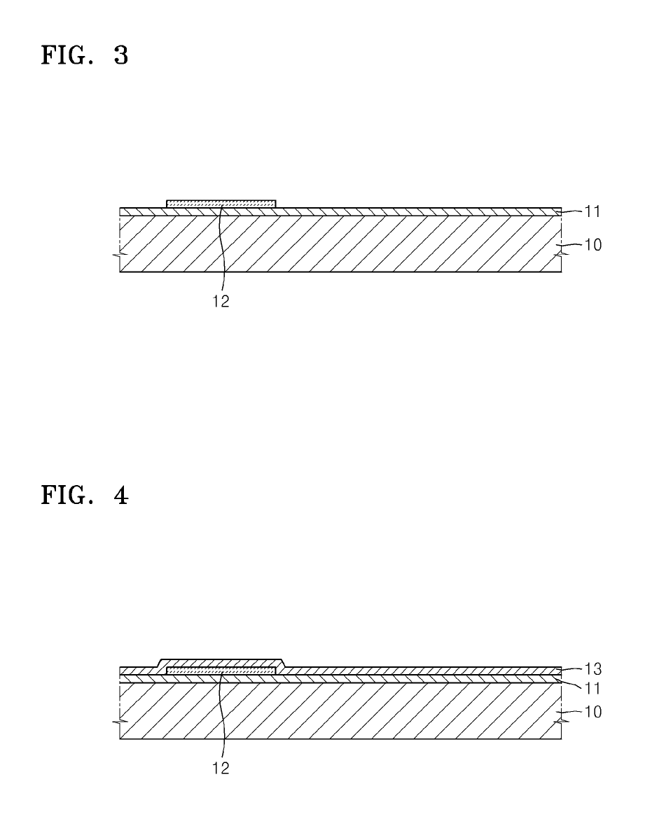

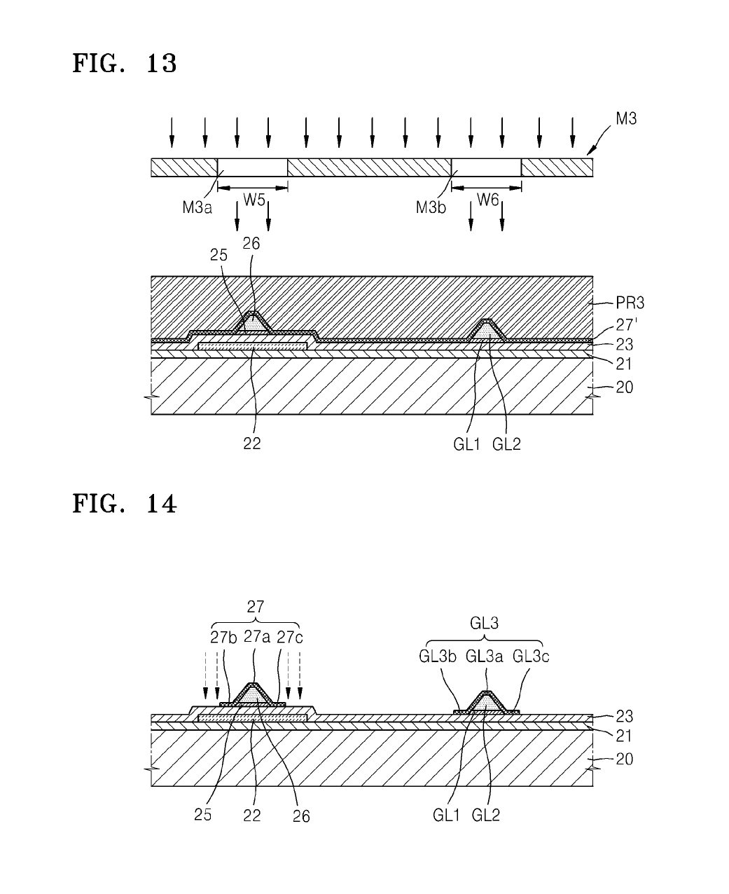

FIGS. 3 to 12 are cross-sectional views sequentially illustrating a manufacturing process of the TFT array substrate shown in FIG. 1.

Referring to FIG. 3, the buffer layer 11 is formed on the substrate 10. The active layer 12 is formed thereon. The active layer 12 may be formed by depositing a semiconductor material by using a deposition method or a sputtering method and then performing a photolithography thereon.

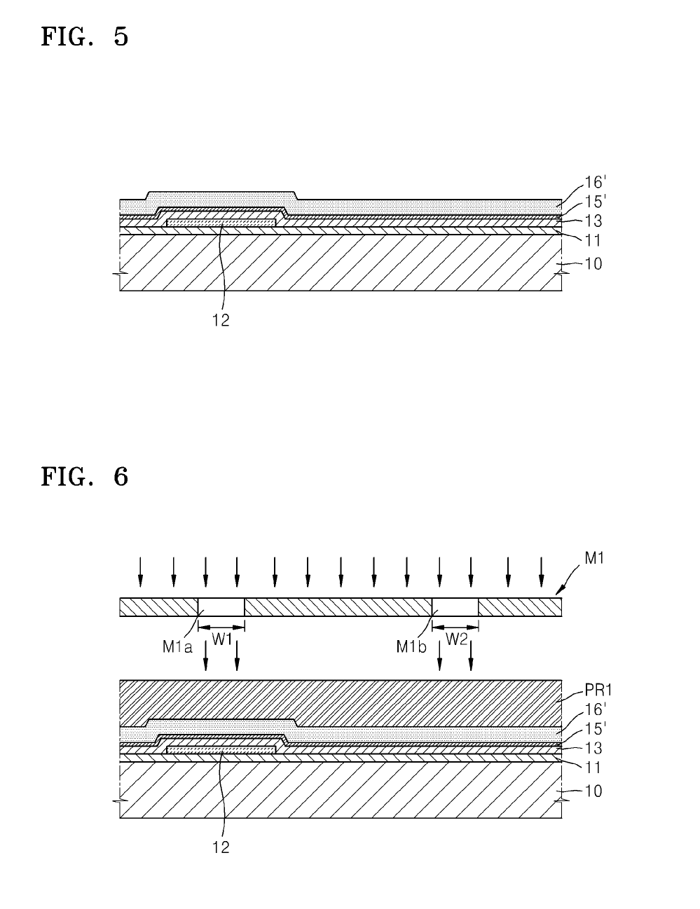

Referring to FIGS. 4 and 5, the gate insulating layer 13 is formed on the buffer layer 12 as to cover the active layer 12, and a first gate line material 15′ and a second gate line material 16′ are formed on the gate insulating layer 13.

The first gate line material 15′ may be Mo or Ti, and the second gate line material 16′ may be Al or Cu.

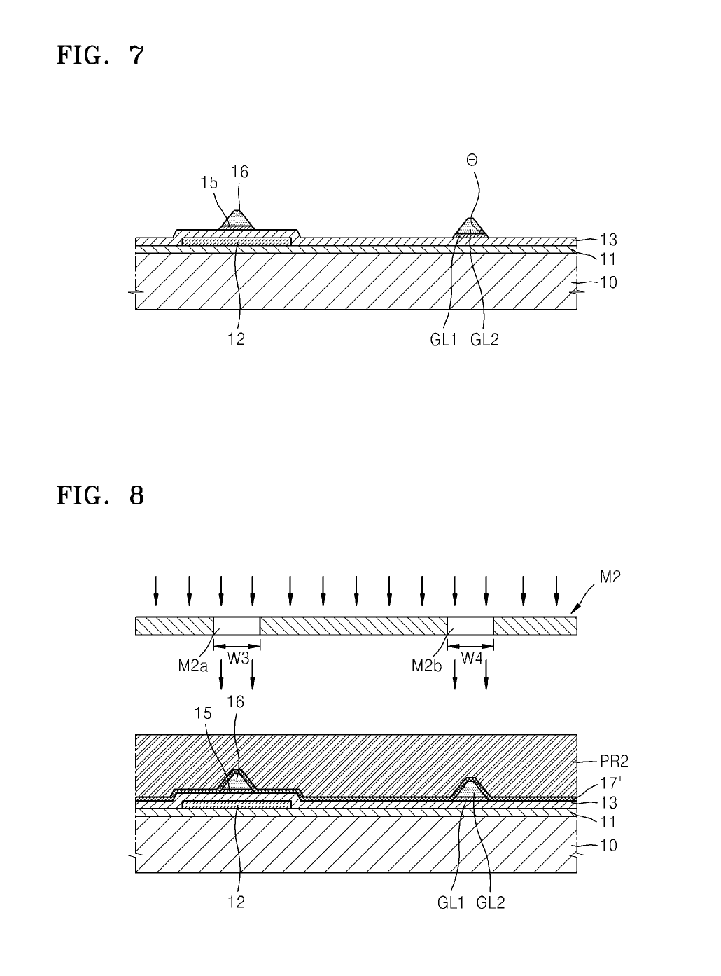

Referring to FIGS. 6 and 7, the first gate line material 15′ and the second gate line material 16′ are coated with a photoresist PR1, and then the first gate line material 15′ and the second gate line material 16′ are patterned by using a first mask M1, thereby forming the first gate line GL1, the second gate line GL2, the first gate electrode 15, and the second gate electrode 16.

The first mask M1 may include a first opening M1a and a second opening M1b. The first opening M1a is located at an area corresponding to the first gate electrode 15 and the second gate electrode 16. The second opening M1b that is located at an area corresponding to the first gate line GL1 and the second gate line GL2.

A width W1 of the first opening M1a and a width W2 of the second opening M1b may be identical to or different from each other.

The first gate line GL1 and the second gate line GL2 are simultaneously etched and thus may have the same etching surfaces. Also, an angle formed by an etching surface of the second gate line GL2 and the substrate 10 may be 50 degrees or less.

A method of manufacturing a TFT array substrate 1 according to one exemplary embodiment of the disclosed technology includes patterning a third gate line GL3 (see FIG. 10) after patterning a first gate line GL1 and a second gate line GL2.

After forming a third gate line material 17′ on a second gate line material 16′, when the first gate line GL1, the second gate line GL2, and the third gate line GL3 are simultaneously patterned, a tilt angle of the second gate line GL2 with respect to a substrate 10 may be too large. The side portions of the third gate line GL3 may protrude outside the etching surface of the second gate line GL2.

However, the TFT array substrate 1 of the present embodiment is formed by patterning the first gate line GL1 and the second gate line GL2 first and then patterning the third gate line GL3 shown in FIG. 10. As such, an angle formed by the etching surface of the second gate line GL2 and the substrate 10 may be small. The angle may be 50 degree or less. In this regard, a protruding phenomenon of the third gate line GL3 can be prevented.

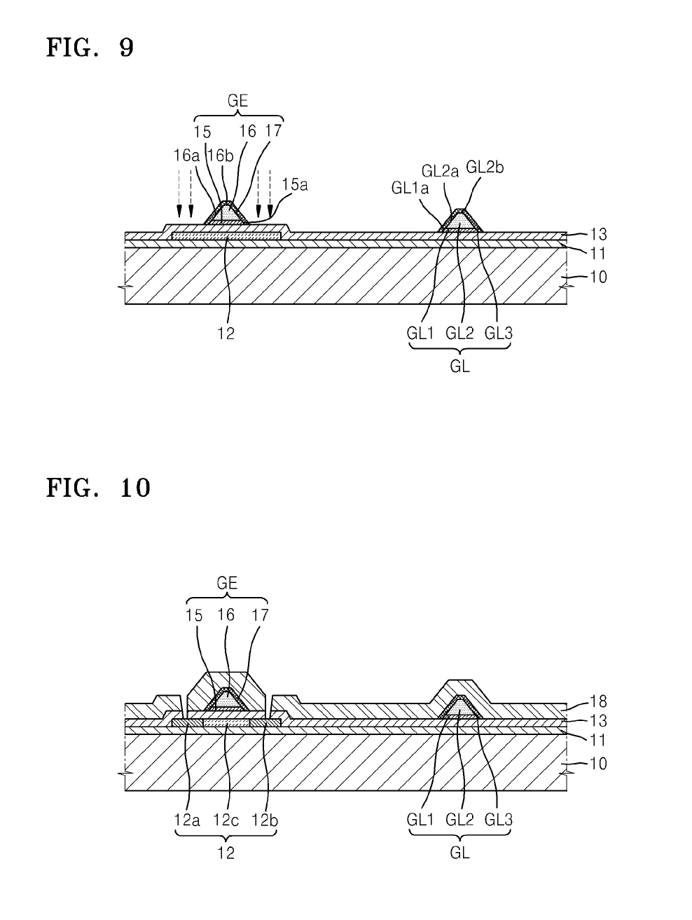

Referring to FIGS. 8 and 9, the third gate line material 17′ is formed on the gate insulating layer 13 as to cover the first gate line GL1 and the second gate line GL2. The third gate line material 17′ is coated with a photoresist PR2. Then, the third gate line material 17′ is patterned by using a second mask M2, thereby forming the third gate line GL3 and the third gate electrode 17.

The third gate line GL3 is formed as to cover a top surface (GL2b) of the second gate line GL2 and side portions (GL1a, GL2a) of the first gate line GL1 and the second gate line GL2. The third gate electrode 17 is formed as to cover a top surface (16b) of the second gate electrode 16 and the side portions (15a, 16a) of the first gate electrode 15 and the second gate electrode 16.

The second mask M2 may include a third opening M2a and a fourth opening M2b. The third opening M2a is located at an area corresponding to the third gate electrode 17. The fourth opening M2b that is located at an area corresponding to the third gate line GL3.

A width W3 of the third opening M2a may be the same with the width W1 of the first opening M1a, and a width W4 of the fourth opening M2b may be the same with the width W2 of the second opening M1b of the first mask M1.

Referring to FIG. 9, after forming the third gate line GL3 and the third gate electrode 17, impurities may be doped in the active layer 12 by using the gate electrode GE as a mask.

Referring to FIG. 10, the interlayer insulating layer 18 is formed on the gate insulating layer 13 as to cover the gate electrode GE and the gate line GL. Then, a contact hole is formed and exposes at least a part of the source area 12a and the drain area 12b of the active layer 12.

Although not shown, a high-temperature process for activating the active layer 12 may be performed after forming the interlayer insulating layer 18. As described above, when heat for the high temperature is transferred to the gate line GL and the gate electrode GE, Al included in the second gate line GL2 and the second gate electrode 16 may penetrate into the interlayer insulating layer 18.

However, in the current embodiment, the third gate line GL3 and the third gate electrode 17 including Mo, each respectively, cover the second gate line GL2 and the second gate electrode 16. As such, Al included in the second gate line GL2 and the second gate electrode 16 may be prevented from penetrating into the interlayer insulating layer 18. In this regard, the active layer 12 can be activated at a temperature of 600° C. or higher. The charge carrier mobility of the active layer 12 can sufficiently increase.

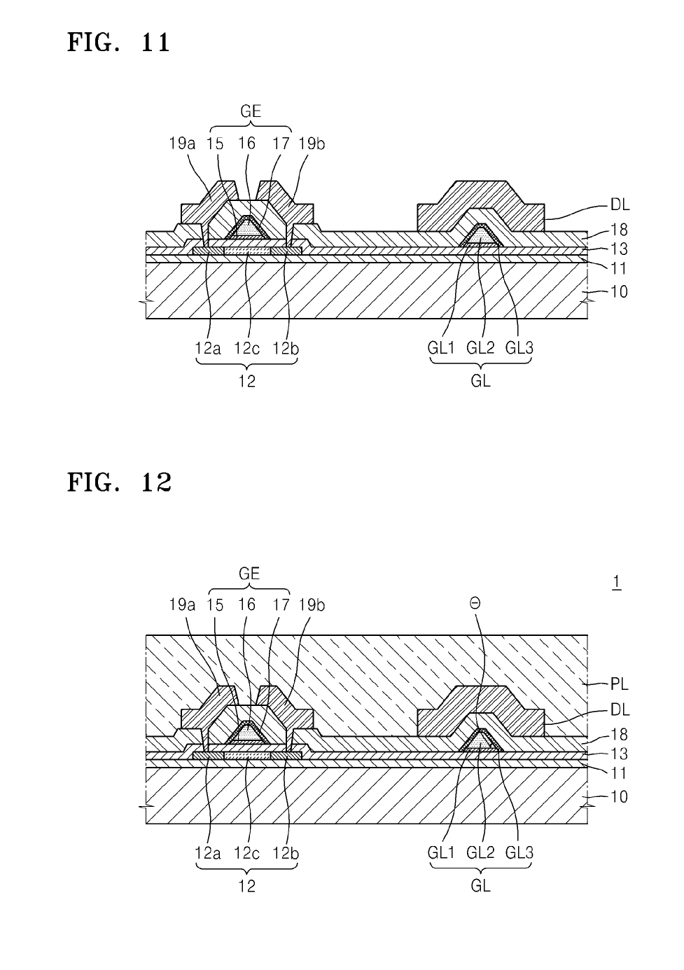

Referring to FIG. 11, a data line DL, a source electrode 19a, and a drain electrode 19b are formed on the interlayer insulating layer 18. A planarization layer PL is formed on the data line DL as to cover the data line DL, the source electrode 19a, and the drain electrode 19b.

The source electrode 19a and the drain electrode 19b may each be electrically connected to a source area 12a and a drain area 12b of the active layer 12 through the contact hole formed in the interlayer insulating layer 18.

The data line DL is separated from the gate line GL with the interlayer insulating layer 18 formed therebetween. As described above, short circuits may occur between the data line DL and the gate line GL when the second gate line GL2 included in the gate line GL penetrates the interlayer insulating layer 18 due to the heat.

However, the TFT array substrate 1 of the present embodiment includes the second gate line GL2 that covers the third gate line GL3.As such, the short circuits between the gate line GL and the data line DL may be prevented.

An angle (θ) between the etching surface of the second gate line GL2 and the substrate 10 may be 50 degrees or less. In this regard, side portions of the data line DL and the gate line GL may be smoothly covered.

As described above, when the angle between the etching surface of the second gate line GL2 and the substrate 10 is too large and an end part of the third gate line GL3 is protruded outside the etching surface of the second gate line GL2, the data line DL may be disconnected without smoothly covering the end part of the gate line GL.

However, the problems described above may be removed by using the TFT array substrate 1 of the present embodiment.

FIGS. 13 to 15 are cross-sectional views sequentially illustrating a process of manufacturing the TFT array substrate shown in FIG. 2.

FIGS. 13 to 15 illustrate a process of manufacturing the third gate line GL3 and the third gate electrode 27 included in the TFT array substrate 2 shown in FIG. 2, and processes of forming other elements of the TFT array substrate 2 shown in FIG. 2 are the same with a method of manufacturing the TFT array substrate 1 shown in FIG. 1.

Referring to FIGS. 13 and 14, the third gate line material 27′ is formed on the gate insulating layer 23 as to cover the first gate line GL1 and the second gate line GL2, the third gate line material 27′ is coated with a photoresist PR3, and then the third gate line material 27′ is patterned by using a third mask M3, thereby forming the third gate line GL3 and the third gate electrode 27.

The third gate line GL3 is formed as to cover a top surface of the second gate line GL2 and side portions of the first gate line GL1 and the second gate line GL2. The third gate electrode 27 is formed as to cover a top surface of the second gate electrode 26 and side portions of the first gate electrode 15 and the second gate electrode 26.

The third mask M3 may include a fifth opening M3a that is located at an area corresponding to the third gate electrode 27 and a sixth opening M3b that is located at an area corresponding to the third gate line GL3.

A width W5 of the fifth opening M3a is larger than the width W1 of the first opening M1a of the first mask M1 shown in FIG. 7. A width W6 of the sixth opening M3b is larger than the width W2 of the second opening M1b of the first mask M1 shown in FIG. 7.

In one embodiment, the third gate line GL3 formed by using the third mask M3 includes a first area GL3a and second areas GL3b and GL3c . The first area GL3a covers the first gate line GL1 and the second gate line GL2. The second areas GL3b and GL3c extend from the first area GL3a in a direction that changes to be parallel to the substrate 20.

The third gate electrode 27, as well as the third gate line GL3, may include a first area 27a and second areas 27b and 27c. The first area 27a covers the first gate electrode 25 and the second gate electrode 26. The second areas 27b and 27c are extended from the first area 27a in a direction that is changed to be parallel to the substrate 20.

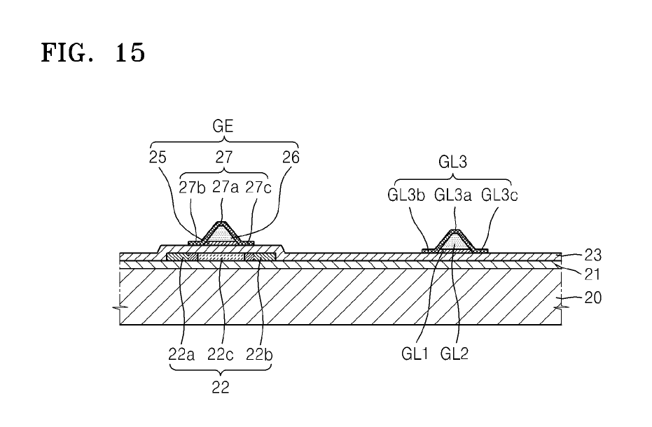

Referring to FIGS. 14 and 15, impurities are doped in the active layer by using the gate electrode GE as a mask. Here, the second areas 27b and 27c included in the third gate electrode serves as a halftone mask. Therefore, impurities are not doped in an area corresponding to an area of the active layer 22 on which the first gate electrode 25, second gate electrode 26, and third gate electrode 27 are stacked. A small amount of impurities are doped in areas corresponding to the second areas 27b and 27c included in the third gate electrode 27. A relatively large amount of impurities are doped in areas on which the gate electrode GE is not formed.

Widths of the second areas 27b and 27c included in the third gate electrode 27, i.e., the areas doped with a small amount of impurities, may be controlled by controlling the width W5 of the fifth opening M3a included in the third mask M3. In the same manner, widths of the second areas GL3b and GL3c of the third gate line GL3 may be controlled by controlling the width W6 of the sixth opening M3b.

A channel area 22c, a source area 22a, and a drain area 22b of the active layer 22 may be formed by the doping processes.

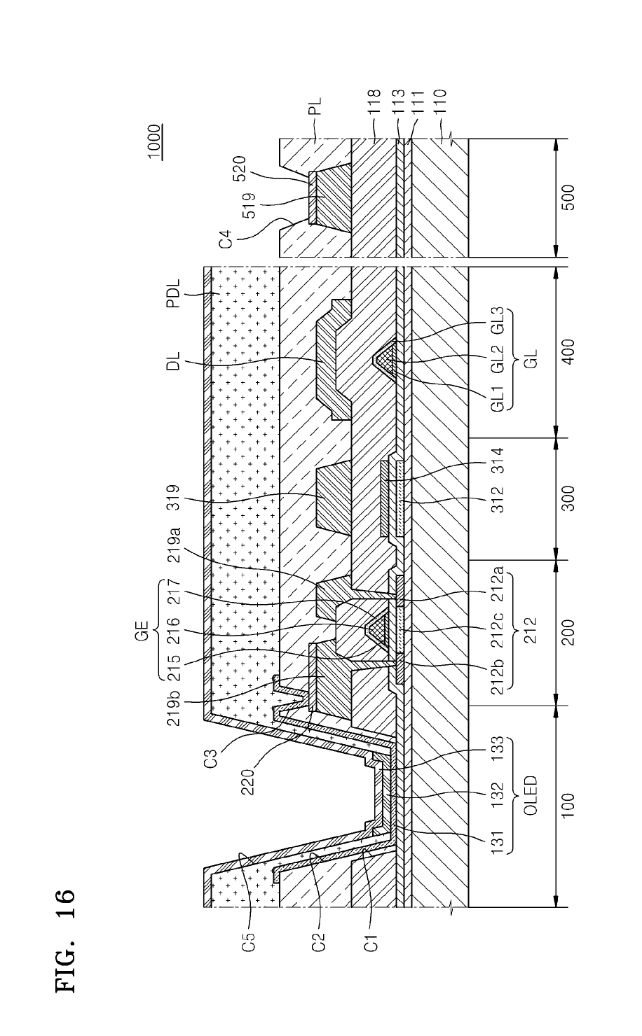

FIG. 16 is a schematic cross-section view of an organic light-emitting display apparatus 1000 according to an embodiment of the disclosed technology.

Referring to FIG. 16, the organic light-emitting display apparatus 1000 includes a pixel area 100, in which an intermediate layer 132 including an organic emission layer on a substrate 110 is included, a transistor area 200 including at least one TFT, a capacitor area 300 including at least one capacitor, a wiring area 400, and a pad area 500.

The substrate 110 may be a glass substrate or a transparent plastic substrate, and a buffer layer 111 may be formed on the substrate 110.

An active layer 212 of the TFT is formed on the transistor area 200 on the buffer layer 111. The active layer 212 may be formed to contain various materials. For example, the active layer 212 may be formed of an inorganic semiconductor material, such as amorphous silicon or crystalline silicon. In this case, the active layer 212 may include a channel area 212c and a source area 212a and a drain area 212b. The source area 212a and the drain area 212b are formed at both edges of the channel area 212c and doped with ion impurities. In one embodiment, the active layer 212 may contain an oxide semiconductor. In another embodiment, the active layer 212 may be formed of an organic semiconductor material.

A gate electrode GE is formed at a location corresponding to the channel area 212c of the active layer 212 with a gate insulating layer 113 formed therebetween. The gate electrode GE may include a first gate electrode 215, a second gate electrode 216, and a third gate electrode 217. In an embodiment, the first gate electrode 215 and the third gate electrode 217 are formed of Mo or Ti, and the second gate electrode 216 are formed of Al or Cu.

A source electrode 219a and a drain electrode 219b each are respectively connected to the source area 212a and the drain area 212b of the active layer 212. The source electrode 219a and the drain electrode 219b are formed on the gate electrode GE with an interlayer insulating layer 118 formed therebetween. The source electrode 219a and the drain electrode 219b may have a structure including at least two metal layers having different electron mobility. In one exemplary implementation, the two metal layers are selected from Al, Pt, Pd, Ag, Mg, Au, Ni, Nd, Ir, Cr, Li, Ca, Mo, Ti, W, Cu, and an alloy thereof.

A planarization layer PL may be formed on the interlayer insulating layer 118 as to cover the source electrode 217a and the drain electrode 217b.

The gate insulating layer 113 and the interlayer insulating layer 118 may have a structure of a single or multiple inorganic insulating layers. The planarization layer PL may be formed of an inorganic insulating layer.

A pixel defining layer PDL is formed on the planarization layer PL. The pixel defining layer PDL may be formed of an organic insulating layer.

In the pixel area 100, the buffer layer 111 and the gate insulating layer 113 are sequentially formed on the substrate 110. A pixel electrode 131 is formed on the gate insulating layer 113.

The pixel electrode 131 is formed in an opening C2 formed in the planarization layer PL, and the pixel defining layer PDL including an opening C5 that is form in a location corresponding to the opening C2 included in the planarization layer PL is covered with both edges of the pixel electrode 131.

Also, the interlayer insulating layer 118 includes an opening C1 formed in a location corresponding to the opening C2 included in the planarization layer PL. The opening C1 included in the interlayer insulating layer 118, the opening C2 included in the planarization layer PL, and an opening C5 included in the pixel defining layer PDL are formed to overlap with each other. The opening C2 included in the planarization layer PL may have a larger area than that of the opening C5 in the pixel defining layer PDL. The opening C2 may have a smaller area than that of the opening C1 in the interlayer insulating layer 118.

An side portion of the pixel electrode 131 is on a top surface in the planarization layer PL and is covered by the pixel defining layer PDL. A part of the pixel electrode 131 is exposed by the pixel defining layer PDL.

The planarization layer PL may include a contact hole C3 that electrically connects the pixel electrode 131 to one of the source electrode 219a and the drain electrode 219b. In the current embodiment, the pixel electrode 131 is electrically connected to the drain electrode 219b.

That is, the drain electrode 219b and a contact layer 220 formed on the drain electrode 219b are formed under the contact hole C3. The pixel electrode 131 located in the contact hole C3 is electrically connected to the drain electrode 219b as directly in contact with the contact layer 220.

The pixel electrode 131 may include a semi-transmissive metal layer. Also, the pixel electrode 131 may further include transparent conductive oxide layers. The transparent conductive oxide layers are respectively formed in lower part and an upper part of the semi-transmissive metal layer and protect the semi-transmissive metal layer.

The semi-transmissive metal layer may be formed of Ag or a silver alloy. Also, the semi-transmissive metal layer along with a counter electrode 133, which is a reflective electrode, forms microcavity. As such, light efficiency and color purity of the organic light-emitting display apparatus 1000 may improve.

An intermediate layer 132 may be formed on the pixel electrode 131. The intermediate layer 132 includes an organic emission layer and may further include at least one of a hole injection layer (HIL), a hole transport layer (HTL), an electron transport layer (ETL), and an electron injection layer (EIL) in addition to the organic emission layer. In some embodiments, the intermediate layer 132 may include various functional layers in addition to an organic emission layer.

The intermediate layer 132 in FIG. 16 is shown as located only under the opening C5 included in the pixel defining layer PDL, but this is only for descriptional convenience, and not the location of the intermediate layer 132 is not limited thereto. That is, the organic emission layer included in the intermediate layer 132 may be extended and formed along an etched surface of the opening C5 in the pixel defining layer PDL to a top surface of the pixel defining layer PDL, and the functional layers in the intermediate layer 132 may be extended to other pixels.

The counter electrode 133 may be formed on the intermediate layer 132.

The counter electrode 133 may be a reflective electrode including a reflective material, and the reflective material may be at least one selected from the group consisting of Al, Mg, Li, Ca, LiF/Ca, and LiF/Al.

Therefore, the organic light-emitting display apparatus 1000 of the current embodiment may be a bottom-emission type, of which light emitted from the intermediate layer 132 reflects on the counter electrode 133, transmits through the pixel electrode 131, and emits toward the substrate 110.

In the capacitor area 300, the buffer layer 111 is formed on the substrate 110. A capacitor including a first electrode 312 is formed on the same layer with the active layer 212. A second electrode 314 is formed on the same layer with the gate electrode GE. A third electrode 319 is formed on the same layer with the source electrode 219a and the drain electrode 219b is formed on the buffer layer 111.

The first electrode 312 of the capacitor may be formed of a semiconductor doped with ion impurities in the same manner as the source area 212a and the drain area 212b of the active layer 212 are formed.

Although the second electrode 314 of the capacitor is located on the gate insulating layer 113 as the gate electrode GE is, but a material of the second electrode 314 is different from that of the gate electrode GE. The material of the second electrode 314 may be formed of a transparent conductive oxide. The first electrode 312 is doped with ion impurities through the transparent second electrode 314, and thus the capacitor of the current embodiment may have a metal-insulator-metal (MIM) structure.

The third electrode 319 of the capacitor may be formed of the same material used in forming the source electrode 219a and the drain electrode 219b. The first electrode 312, the second electrode 314, and the third electrode 319 included in the capacitor constitute a plurality of capacitors connected in parallel, and thus a capacitance of the organic light-emitting display apparatus 1000 of the current embodiment may increase without increasing a surface area of the capacitor. Therefore, a surface area of the capacitor with respect to the increased capacitance, and thus an aperture ratio may increase.

In the wiring area 400, the buffer layer 111 and the gate insulating layer 113 are sequentially formed on the substrate 110, and a gate line GL including a first gate line GL1, a second gate line GL2, and a third gate line GL3 is formed on gate insulating layer 113.

The third gate line GL3 may be formed as to cover a top surface of the second gate line GL2 and side portions of the first gate line GL1 and the second gate line GL2.

The first gate line GL1, second gate line GL2, and third gate line GL3 may be each respectively formed on the same layer and with the same material of the first gate electrode 215, second gate electrode 216, and third gate electrode 217.

In the pad area 500, a first pad layer 519 and a second pad layer 520 are formed on the interlayer insulating layer 118.

The first pad layer 519 may include a plurality of metal layers having different electron mobility as well as the source electrode 219a and the drain electrode 219b. In one exemplary implementation, the first pad layer 519 has a structure including multiple layers of at least one metal selected from Al, Pt, Pd, Ag, Mg, Au, Ni, Nd, Ir, Cr, Li, Ca, Mo, Ti, W, and Cu.

The second pad layer 520 may be formed of a transparent conductive oxide. The second pad layer 520 can prevent the first pad layer 519 from being exposed to moisture and oxygen, and thus decline of reliability of a pad may be prevented. The second pad layer 520 may be formed of the same material with the contact layer 220 formed under the contact hole C3.

The first pad layer 519 is not exposed to an etchant during etching of the pixel electrode 131 because the second pad layer 520 that is a protection layer is formed on an upper portion of the first pad layer 519.

Moreover, since side portions of the first pad layer 519 sensitive to external environment, such as moisture or oxygen, are covered with the planarization layer PL, the side portions of the first pad layer 519 are not exposed to an etchant during etching of the pixel electrode 131.

Although not shown in FIG. 16, the organic light-emitting display apparatus 1000 of the current embodiment may further include a sealing member (not shown) that seals a display area including the pixel area 100, the transistor area 200, the capacitor area 300, and the wiring area 400. The sealing member may be formed of a substrate including a glass material or a plastic material, a metal film, or a thin film encapsulation in which an organic insulating layer and an inorganic insulating layer are alternatively arranged.

As described above, according to various exemplary embodiments of the disclosed technology, a TFT array substrate, an organic light-emitting display apparatus, and a manufacturing method thereof prevent short circuits occurring in gate lines and data lines, prevent disconnections of a data line and improve TFT characteristics.

For purposes of summarizing the disclosed technology, certain aspects, advantages and novel features of the disclosed technology have been described herein. It is to be understood that not necessarily all such advantages is achieved in accordance with any particular embodiment of the disclosed technology. Thus, the disclosed technology is embodied or carried out in a manner that achieves or optimizes one advantage or group of advantages as taught herein without necessarily achieving other advantages as is taught or suggested herein.

Various modifications of the above described embodiments will be readily apparent, and the generic principles defined herein is applied to other embodiments without departing from the spirit or scope of the disclosed technology. Thus, the disclosed technology is not intended to be limited to the embodiments shown herein but is to be accorded the widest scope consistent with the principles and novel features disclosed herein.

It should be understood that the exemplary embodiments described therein should be considered in a descriptive sense only and not for purposes of limitation. Descriptions of features or aspects within each embodiment should typically be considered as available for other similar features or aspects in other embodiments.

While one or more embodiments of the disclosed technology have been described with reference to the figures, it will be understood by those of ordinary skill in the art that various changes in form and details may be made therein without departing from the spirit and scope of the disclosed technology as defined by the following claims.

What is claimed is:

1. A thin film transistor (TFT) array substrate, comprising:
a substrate;
a first gate line formed on the substrate;
a second gate line formed on the first gate line; and
a third gate line formed on the second gate line and configured to cover a top surface of the second gate line and the side portions of the first gate line and the second gate line.

2. The TFT array substrate of claim 1, wherein the third gate line comprises
a first area configured to cover the first gate line and the second gate line; and
a plurality of second areas that extend from the first area and in a direction that is parallel to the substrate.

3. The TFT array substrate of claim 1, wherein the second gate line is formed of aluminum (Al).

4. The TFT array substrate of claim 1, wherein the first gate line and the second gate line have the same etching surfaces.

5. The TFT array substrate of claim 1, wherein the angle between the substrate and the etching surface of the second gate line is 50 degrees or less.

6. The TFT array substrate of claim 1 further comprising:
an interlayer insulating layer formed on the third gate line, and
a data line formed on the interlayer insulating layer.

7. The TFT array substrate of claim 6 further comprising a TFT formed on the substrate, wherein the TFT includes:
an active layer comprising a channel area, a source area, and a drain area;
a gate electrode formed on an area corresponding to the channel area and insulated from the active layer; and
a source electrode and a drain electrode and formed on the same layer with the data line and each electrode is respectively electrically connected with the source area and the drain area.

8. The TFT array substrate of claim 7, wherein the gate electrode comprises a first gate electrode, a second gate electrode and a third gate electrode that are each respectively formed on the same layer with the first gate line, the second gate line, and the third gate line, and wherein the third gate electrode comprises:
a first area that covers the first gate electrode and the second gate electrode, and
a plurality of second areas that extend from the first area and in a direction that is parallel to the substrate.

9. The TFT array substrate of claim 8, wherein the active layer comprises:
a channel area that is formed in an area corresponding to the first area of the third gate electrode, and
a source area and a drain area corresponding to both edges of the channel area and doped with impurities, and wherein the portions of the source area and the drain area corresponding to the second areas of the third gate electrode are doped with an amount of impurities less than other portions of the source area and the drain area.

10. A method of manufacturing a TFT array substrate, the method comprising:
forming a first gate line material and a second gate line material on a substrate;
forming a first gate line and a second gate line by patterning the first gate line material and the second gate line material;
forming a third gate line material on the second gate line; and
forming a third gate line to cover a top surface of the second gate line and side portions of the first gate line by patterning the third gate line material.

11. The method of claim 10, wherein forming the first gate line and the second gate line comprises forming the first gate line and the second gate line by patterning the first gate line material and the second gate line material by using a first mask, and wherein forming the third gate line comprises forming the third gate line by patterning the third gate line material by using a second mask.

12. The method of claim 11, wherein the width of an opening of the first mask corresponding to the first gate line and the second gate line is the same as the width of an opening of the second mask corresponding to the third gate line.

13. The method of claim 11, wherein the width of an opening of the first mask corresponding to the first gate line and the second gate line is the smaller than a width of an opening of the second mask corresponding to the third gate line.

14. The method of claim 10, further comprising:
forming an interlayer insulating layer on the third gate line, and
forming a data line on the interlayer insulating layer.

15. The method of claim 10, further comprising forming a TFT on the substrate, wherein forming the TFT includes:
forming an active layer on the substrate;
forming a gate insulating layer and a gate electrode on the active layer; and
forming a source electrode and a drain electrode on the gate electrode.

16. The method of claim 15, wherein forming the gate electrode comprises forming a first gate electrode, a second gate electrode and a third gate electrode by the same processes each respectively with the processes for forming the first gate line, the second gate line and the third gate line.

17. The method of claim 16, wherein forming the third gate electrode comprises:
forming a first area to cover the first gate electrode and the second gate electrode, and
forming a plurality of second areas that extend from the first area and in a direction that is parallel to the substrate.

18. The method of claim 16, further comprising doping impurities in the active layer by using the first gate electrode, the second gate electrode and the third gate electrode as a mask.

19. An organic light-emitting diode (OLED) display, wherein the display comprises:
a plurality of gate lines that are extended in a first direction;
a plurality of data lines that are insulated from the gate lines by an interlayer insulating layer and extended in a second direction intersecting the first direction;
a pixel that is electrically connected to the gate lines and the data lines and comprises a TFT; and
an organic light-emitting device that is included in the pixel, electrically connected with the TFT, and comprises a pixel electrode, a counter electrode, and an intermediate layer, which is formed between the pixel electrode and the counter electrode and emits light,
wherein one of the gate lines comprises:
a first gate line formed on a substrate;
a second gate line formed on the first gate line; and
a third gate line that is formed on the second gate line and covers a top surface of the second gate line and side portions of the first gate line and the second gate line.

20. The OLED display of claim 19, wherein the TFT comprises:
an active layer comprising a channel area, a source area, and a drain area;
a gate electrode that is insulated from the active layer and formed on an area corresponding to the channel area; and
a source electrode and a drain electrode that are each respectively electrically connected with the source area and the drain area of the active layer and formed on the same layer with the data line,
wherein the organic light-emitting apparatus further comprises
a pad electrode comprising a first pad layer that is formed on the same layer with the source electrode and the drain electrode and a second pad layer formed on the first pad layer;
a capacitor comprising a first electrode formed on the same layer with the active layer, a second electrode formed on the same layer with the gate electrode, and a third electrode formed on the same layer with the source and drain electrodes;
a planarization layer that covers the source and drain electrode and comprises an opening in which the pixel electrode is formed; and
a pixel defining layer comprising an opening formed in an area corresponding to the opening comprised in the planarization layer and covers side portions of the pixel electrode.
